(19) United States
(12) Patent Application Publication
(10) Pub. No.: US 2012/0280275 A1
(43) Pub. Date: Nov. 8, 2012

(54) SEMICONDUCTOR WAFER, ELECTRONIC DEVICE, AND METHOD FOR PRODUCING SEMICONDUCTOR WAFER

(75) Inventors: Masahiko HATA, Tsuchiura-shi (JP); Hiroyuki SAZAWA, Tsukuba-shi (JP)

(73) Assignee: SUMITOMO CHEMICAL COMPANY, LIMITED, Tokyo (JP)

(21) Appl. No.: 13/548,837

(22) Filed: Jul. 13, 2012

Related U.S. Application Data
(63) Continuation-in-part of application No. PCT/JP2011/000141, filed on Jan. 13, 2011.

(30) Foreign Application Priority Data
Jan. 15, 2010 (JP) 2010-007463

(51) Int. Cl. H01L 29/267; H01L 21/20

(52) U.S. Cl. 257/183; 438/478; 257/E21.09; 257/E29.081

(57) ABSTRACT

Provided is a semiconductor wafer including: a base wafer whose surface is made of a silicon crystal: a SiₓGe₁₋ₓC (0≦x<1) epitaxial crystal formed in a partial area of the silicon crystal; and a Group 3 nitride semiconductor crystal formed on the SiₓGe₁₋ₓC (0≦x<1) epitaxial crystal. In one example, the semiconductor wafer includes an inhibitor that is formed on the silicon crystal, contains an aperture exposing the silicon crystal, and inhibits crystal growth, and the SiₓGe₁₋ₓC (0≦x<1) epitaxial crystal is formed in the aperture.

### TECHNICAL FIELD

The present invention relates to a semiconductor wafer, an electronic device, and a method for producing a semiconductor wafer.

The contents of the following Japanese patent application and PCT patent application are incorporated herein by reference:
JP2010-007463 filed on Jan. 15, 2010, and
PCT/JP2011/000141 filed on Jan. 13, 2011.

### BACKGROUND ART

Patent Document 1 discloses a single crystal gallium nitride localized wafer suited for producing an electro-optical device on which an electronic device and an optical device are together installed on the same silicon wafer. Such a single crystal gallium nitride localized wafer includes a region on a silicon wafer in which single crystal gallium nitride has been grown by forming silicon carbide on the silicon wafer, and locally forming single crystal gallium nitride on the silicon carbide. Patent Document 1 discloses using silicon nitride as a mask for forming single crystal gallium nitride.
Patent Document 1: JP2004-179242A

### SUMMARY OF THE INVENTION

### Problems to be Solved by the Invention

However, silicon carbide disclosed in Patent Document 1 is an altered layer obtained by subjecting the surface of the silicon wafer to thermal processing using a mixture of a hydrocarbon gas and a hydrogen gas. Therefore, the single crystal gallium nitride formed on the silicon carbide cannot have sufficiently favorable crystallinity. In addition, silicon carbide tends to cause such defects as dislocation attributed lattice mismatch because the crystal lattice constant of silicon carbide is different from that of silicon and is also slightly different from that of gallium nitride. This has made it difficult to maintain favorable crystallinity of a Group 3 nitride semiconductor such as the single crystal gallium nitride formed on the silicon carbide. A purpose of the present invention is to enhance the crystallinity of a Group 3 nitride semiconductor locally formed on a silicon wafer.

### Means for Solving the Problems

For a solution to the above-mentioned problems, according to the first aspect related to the present invention, provided is a semiconductor wafer including: a base wafer whose surface is made of a silicon crystal: a SiₓGe₁₋ₓC (0≦x<1) epitaxial crystal formed in a partial area of the silicon crystal; and a Group 3 nitride semiconductor crystal formed on the SiₓGe₁₋ₓC (0≦x<1) epitaxial crystal. As an example, an inhibitor that is formed on the silicon crystal, contains an aperture exposing the silicon crystal, and inhibits crystal growth, where the SiₓGe₁₋ₓC (0≦x<1) epitaxial crystal is formed in the aperture.

The above-described semiconductor wafer may further include a SiₓGe₁₋ₓC (0≦x<1) altered layer between the silicon crystal and the SiₓGe₁₋ₓC (0≦x<1) epitaxial crystal, the SiₓGe₁₋ₓC (0≦x<1) altered layer being a SiₓGe₁₋ₓ (0≦x<1) layer that is formed on a surface of the silicon crystal and whose surface is altered by carbon. The semiconductor wafer may further include a SiₓGe₁₋ₓ (0≦x<1) epitaxial layer formed by epitaxial growth between the silicon crystal and the SiₓGe₁₋ₓC (0≦x<1) epitaxial crystal.

The above-described semiconductor wafer may further include a SiₓGe₁₋ₓ C (0≦x<1) altered layer between the SiₓGe₁₋ₓ (0≦x<1) epitaxial layer and the SiₓGe₁₋ₓC (0≦x<1) epitaxial crystal, the SiₓGe₁₋ₓC (0≦x<1) altered layer being the SiₓGe₁₋ₓ (0≦x<1) epitaxial layer whose surface is altered by carbon. The SiₓGe₁₋ₓ (0≦x<1) epitaxial layer may include one or more semiconductor layers selected from among a P-type semiconductor layer and an N-type semiconductor layer constituting a PN-junction isolation. The SiₓGe₁₋ₓ (0≦x<1) epitaxial layer may include one or more semiconductor layers selected from among a P⁺ type semiconductor layer and an N⁺ type semiconductor layer constituting a tunnel junction.

According to the second aspect related to the present invention, provided is an electronic device comprising an electronic element having, as an active layer, the Group 3 nitride semiconductor crystal in the semiconductor wafer described above. In one example of the described electronic device, the semiconductor wafer includes the Group 3 nitride semiconductor crystal in each of a plurality of areas of the SiₓGe₁₋ₓC (0≦x<1) epitaxial crystal, the electronic element is formed on each of the Group 3 nitride semiconductor crystals, and at least two of the electronic elements are connected to each other either in series or in parallel. The electronic device may further include a silicon element formed by using the silicon crystal of the semiconductor wafer, where the silicon element and the electronic element are connected to each other.

According to the third aspect related to the present invention, provided is a method for producing a semiconductor wafer, including: forming an inhibitor to inhibit crystal growth, on a silicon crystal of a base wafer whose surface is made of the silicon crystal; forming an aperture from a surface of the inhibitor to reach the silicon crystal; forming a SiₓGe₁₋ₓC (0≦x<1) epitaxial crystal on the silicon crystal exposed in the aperture; and forming a Group 3 nitride semiconductor crystal on the a SiₓGe₁₋ₓC (0≦x<1) epitaxial crystal.

The described method may further include forming, between the step of forming the inhibitor and the step of forming the Group 3 nitride semiconductor crystal, a SiₓGe₁₋ₓC (0≦x<1) altered layer by altering, using carbon, a surface of a SiₓGe₁₋ₓ (0≦x<1) layer formed on a surface of the silicon crystal exposed in aperture, where in forming the SiₓGe₁₋ₓC (0≦x<1) epitaxial crystal, the SiₓGe₁₋ₓC (0≦x<1) epitaxial crystal is formed on the SiₓGe₁₋ₓC (0≦x<1) altered layer.

According to the fourth aspect related to the present invention, provided is a method for producing a semiconductor wafer, including: forming an inhibitor to inhibit crystal growth, on a silicon crystal of a base wafer whose surface is made of the silicon crystal; forming an aperture from a surface of the inhibitor to reach the silicon crystal; forming a SiₓGe₁₋ₓ (0≦x<1) epitaxial layer on the silicon crystal exposed in the aperture; forming a SiₓGe₁₋ₓC (0≦x<1) epitaxial crystal on the SiₓGe₁₋ₓC (0≦x<1) epitaxial layer; and forming a Group 3 nitride semiconductor crystal on the SiₓGe₁₋ₓC (0≦x<1) epitaxial crystal.

The method further includes forming a SiₓGe₁₋ₓC (0≦x<1) altered layer by altering a surface of the SiₓGe₁₋ₓ (0≦x<1) epitaxial layer using carbon, between the step of forming the SiₓGe₁₋ₓ (0≦x<1) epitaxial layer and the step of forming the SiₓGe₁₋ₓC (0≦x<1) epitaxial crystal, where in forming the SiₓGe₁₋ₓC (0≦x<1) epitaxial crystal, the SiₓGe₁₋ₓC (0≦x<1) epitaxial, crystal is formed on the SiₓGe₁₋ₓC (0≦x<1) altered layer.

The production methods regarding the third aspect and the fourth aspect may further include cleansing, by etching, a surface of the silicon crystal exposed in the aperture, between the step of forming the aperture and the step of forming the SiₓGe₁₋ₓC (0≦x<1) epitaxial crystal. In addition, according to these methods, such a configuration is possible in which the surface of the silicon crystal is the (111) plane, forming the Group 3 nitride semiconductor crystal includes: a first phase of forming a first Group 3 nitride semiconductor crystal whose facet crystal plane in a plane direction different from the (111) plane is exposed; and a second phase of forming a second Group 3 nitride semiconductor crystal having the (111)A plane parallel to the surface of the base wafer, with the facet crystal plane serving as a seed, where in the first phase, the first Group 3 nitride semiconductor crystal is formed under a condition in which a crystal growth rate in a first direction vertical to the surface of the base wafer is faster than a crystal growth rate in a second direction parallel to the surface of the base wafer, and in the second phase, the second Group 3 nitride semiconductor crystal is formed under a condition in which the crystal growth rate in the second direction is faster than the crystal growth rate in the first direction.

### BRIEF DESCRIPTION OF THE DRAWINGS

FIG. 1A shows an exemplary cross section of a semiconductor wafer 100.

FIG. 1B shows an exemplary cross section of the semiconductor wafer 100 in its production process.

FIG. 1C shows an exemplary cross section of the semiconductor wafer 100 in its production process.

FIG. 2A shows an exemplary cross section of a semiconductor wafer 200.

FIG. 2B shows an exemplary cross section of the semiconductor wafer 200 in its production process.

FIG. 2C shows an exemplary cross section of the semiconductor wafer 200 in its production process.

FIG. 3A shows an exemplary cross section of a semiconductor wafer 300.

FIG. 3B shows an exemplary cross section of the semiconductor wafer 300 in its production process.

FIG. 3C shows an exemplary cross section of the semiconductor wafer 300 in its production process.

FIG. 4A shows an exemplary cross section of a semiconductor wafer 400.

FIG. 4B shows an exemplary cross section of the semiconductor wafer 400 in its production process.

FIG. 4C shows an exemplary cross section of the semiconductor wafer 400 in its production process.

FIG. 5A shows an exemplary cross section of a semiconductor wafer 500.

FIG. 5B shows an exemplary cross section of the semiconductor wafer 500 in its production process.

FIG. 6 shows an exemplary cross section of an electronic device 600.

### MODE FOR CARRYING OUT THE INVENTION

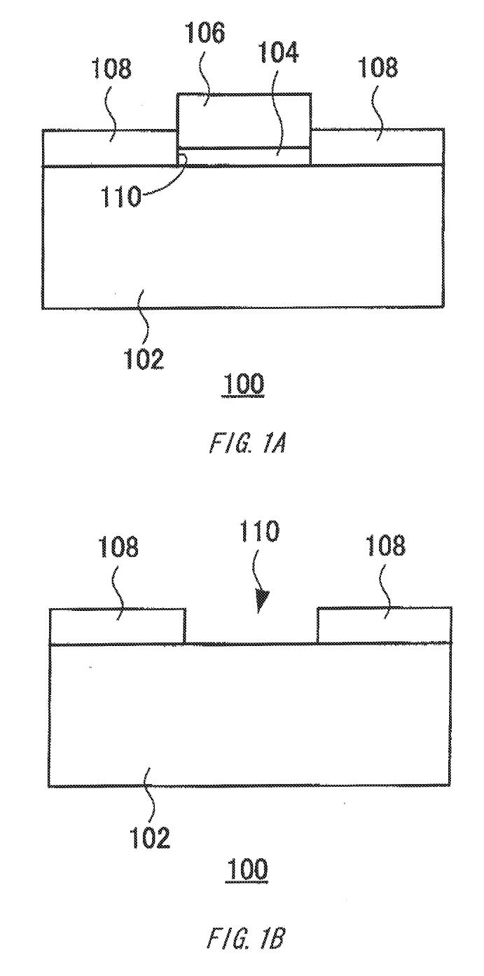

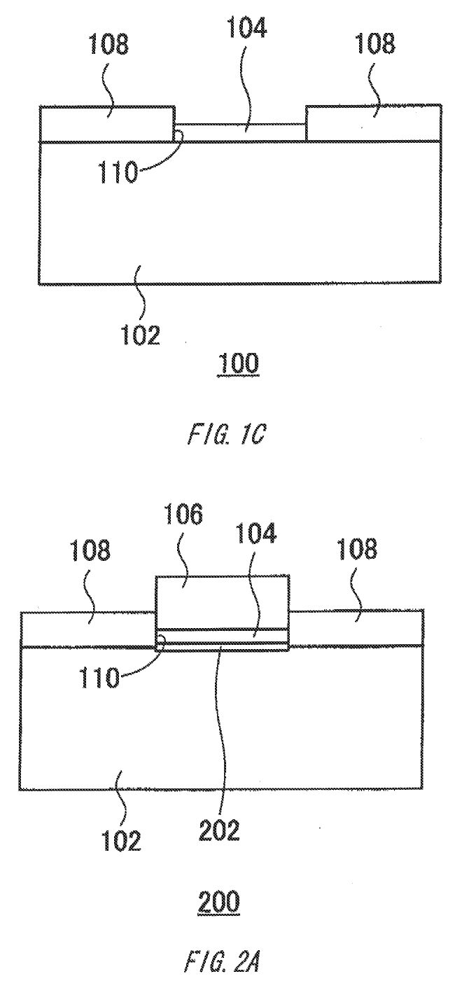

The following explains the present invention through embodiments. FIG. 1A shows an exemplary cross section of a semiconductor wafer 100, and FIG. 1B and FIG. 1C respectively show an exemplary cross section of the semiconductor wafer 100 in its production process.

As shown in FIG. 1A, the semiconductor wafer 100 includes a base wafer 102, a SiₓGe₁₋ₓC (0≦x<1) epitaxial crystal 104, a Group 3-5 compound semiconductor crystal 106, and an in inhibitor 108. An aperture 110 is provided through the inhibitor 108.

The surface of the base wafer 102 is made of a silicon crystal. For example, the base wafer 102 is a SOI (silicon on insulator) wafer made of a silicon crystal in the vicinity of its surface, a silicon wafer whose entirety of the bulk is made of a silicon crystal, or the like.

The SiₓGe₁₋ₓC (0≦x<1) epitaxial crystal 104 is formed by epitaxial growth locally in a partial area of the silicon crystal of the base wafer 102. So as to form the SiₓGe₁₋ₓC (0≦x<1) epitaxial crystal in a partial area of the silicon crystal, it is also possible to adopt a method for patterning using a photolithography method after forming the SiₓGe₁₋ₓC (0≦x<1) epitaxial crystal on the entire plane of the base wafer 102, in addition to the method for forming the aperture 110 through the inhibitor 108 explained below.

The aspect ratio (i.e. the thickness divided by width of a crystal) of the SiₓGe₁₋ₓC (0≦x<1) epitaxial crystal 104 having been formed in a partial area of the silicon crystal of the base wafer 102 is desirably √ 3 or greater.

The Group 3-5 compound semiconductor crystal 106 contains a nitrogen atom. The Group 3-5 compound semiconductor crystal 106 is formed on the SiₓGe₁₋ₓC (0≦x<1) epitaxial crystal 104 having been epitaxially grown. The Group 3-5 compound semiconductor crystal 106 has a favorable crystallinity since it is formed on the SiₓGe₁₋ₓC (0≦x<1) epitaxial crystal 104.

When the SiₓGe₁₋ₓC (0≦x<1) crystal is formed by altering a silicon crystal, for example, the crystallinity of the SiₓGe₁₋ₓC (0≦x<1) crystal is lowered during the altering process. Here, “forming by altering” means incorporation of an atom added to the crystal after alteration into the crystal lattice before alteration. As opposed to this, the SiₓGe₁₋ₓC (0≦x<1) crystal having been formed by epitaxial growth has a better crystallinity than that of the SiₓGe₁₋ₓC (0≦x<1) crystal having formed by altering silicon. The crystallinity of the Group 3-5 compound semiconductor crystal 106 formed on the SiₓGe₁₋ₓC (0≦x<1) epitaxial crystal 104 has a favorable crystallinity because the crystallinity of the crystal layer formed on the crystal is affected by the crystal situated below.

The inhibitor 108 is formed on the silicon crystal of the base wafer 102. The inhibitor 108 inhibits the growth of a crystal. An aperture 110 reaching the silicon crystal of the base wafer 102 is formed through the inhibitor 108. The SiₓGe₁₋ₓC (0≦x<1) epitaxial crystal 104 is formed in the aperture 110 by crystal growth. Since the inhibitor 108 inhibits the crystal growth, the SiₓGe₁₋ₓC (0≦x<1) epitaxial crystal 104 is selectively formed by selective epitaxial growth. The SiₓGe₁₋ₓC (0≦x<1) epitaxial crystal 104 is formed in the aperture 110 by selective epitaxial growth.

The following explains a method for producing the semiconductor wafer 100. As shown in FIG. 1B, the inhibitor 108 is formed on the silicon crystal of the base wafer 102. Thereafter, the aperture 110 is formed from the surface of the inhibitor 108 to reach the silicon crystal. The inhibitor 108 may be silicon oxide, silicon nitride, silicon oxynitride, for example, and may be formed by CVD. Silicon oxide can also be formed by thermal oxidation. The aperture 110 may be formed by photolithography.

Next, the SiₓGe₁₋ₓC (0≦x<1) epitaxial crystal 104 is formed on the silicon crystal exposed in the aperture 110 as shown in FIG. 1C. The SiₓGe₁₋ₓC (0≦x<1) epitaxial crystal 104 is formed by epitaxial growth.

The SiₓGe₁₋ₓC (0≦x<1) epitaxial crystal 104 may for example be grown by CVD using a silicon source, a germanium source, and a carbon source in a gas state. When CVD is thermal CVD, an exemplary growth temperature is from 900 degrees centigrade to 1100 degrees centigrade. An exemplary source of silane and carbon is alkylsilane such as monomethylsilane (SiH₃CH₃). An exemplary source of germanium and carbon is alkylgermane such as monomethylgermane (GeH₃CH₃).

An exemplary silicon source is silicon hydride such as monosilane (SiH₄), and disilane (Si₂H₆). Another silicon sources is silicon halide such as chlorosilane (SiHₓCl₄₋ₓ). An exemplary germanium source is germanium hydride such as monogermane (GeH₄), and digermane (Ge₂H₆). Another germanium source is germanium halide such as chlorogermane (GeHₓCl₄₋ₓ). An exemplary carbon source is hydrocarbon such as methane, ethane, and propane.

In this case, it is preferable to conduct selective growth so as to form the SiₓGe₁₋ₓC (0≦x<1) epitaxial crystal 104 only in the aperture 110 and no crystal growth is caused on the inhibitor 108. Note that even when a polycrystal and so on of SiₓGe₁₋ₓC (0≦x<1) precipitates on the inhibitor 108, the SiₓGe₁₋ₓC (0≦x<1) epitaxial crystal 104 in the aperture 110 may also be used in the later processes. It is also possible to remove the polycrystal having precipitated on the inhibitor 108 together with the inhibitor 108 while leaving the SiₓGe₁₋ₓC (0≦x<1) epitaxial crystal 104 inside the aperture 110 for later use.

After growth of the SiₓGe₁₋ₓC (0≦x<1) epitaxial crystal 104, the Group 3-5 compound semiconductor crystal 106 is formed by selective epitaxial growth on the SiₓGe₁₋ₓC (0≦x<1) epitaxial crystal 104, thereby forming the semiconductor wafer 100.

As explained above, the semiconductor wafer 100 includes, between the base wafer 102 whose surface is made of silicon and the Group 3-5 compound semiconductor crystal 106, the SiₓGe₁₋ₓC (0≦x<1) epitaxial crystal 104 formed by epitaxial growth, and so the Group 3-5 compound semiconductor crystal 106 has an improved crystallinity. In addition, it is possible to obtain a Group 3-5 compound semiconductor crystal 106 having even better crystallinity, by adjusting the composition x of the SiₓGe₁₋ₓC (0≦x<1) epitaxial crystal 104 and matching the lattice constant of the SiₓGe₁₋ₓC (0≦x<1) epitaxial crystal 104 with the lattice constant of the Group 3-5 compound semiconductor crystal 106 grown on the SiₓGe₁₋ₓC (0≦x<1) epitaxial crystal 104.

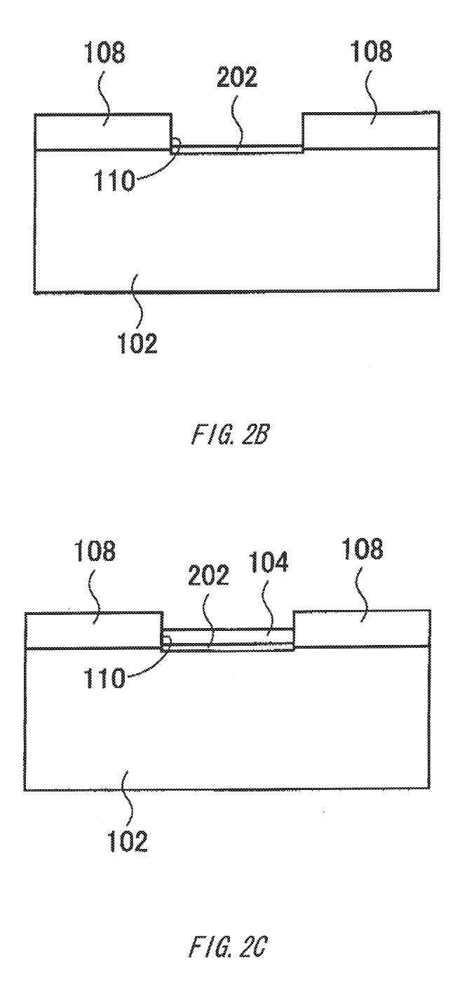

FIG. 2A shows an exemplary cross section of a semiconductor wafer 200. FIG. 2B and FIG. 2C show an exemplary cross section of the semiconductor wafer 200 in its production process. The semiconductor wafer 200 is similar to the semiconductor wafer 100 except that the semiconductor wafer 200 includes a SiₓGe₁₋ₓC (0≦x<1) altered layer 202 between the silicon crystal of the base wafer 102 of the semiconductor wafer 100 and the SiₓGe₁₋ₓC (0≦x<1) epitaxial crystal 104. The following explanation focuses on the difference.

The SiₓGe₁₋ₓC (0≦x<1) altered layer 202 is formed between the silicon crystal of the base wafer 102 and the SiₓGe₁₋ₓC (0≦x<1) epitaxial crystal 104. The SiₓGe₁₋ₓC (0≦x<1) altered layer 202 is formed by altering the surface of the SiₓGe₁₋ₓ (0≦x<1) layer formed on the silicon crystal of the base wafer 102 using carbon.

The semiconductor wafer 200 can be produced in the following manner. First, as shown in FIG. 2B, an aperture 110 is provided through the inhibitor 108 on the base wafer 102. Next, the base wafer 102 provided with the aperture 110 is heated to the range from 1000 degrees centigrade to 1100 degrees centigrade, and the surface of the silicon crystal exposed in the aperture 110 is cleansed in the hydrogen atmosphere, and then the SiₓGe₁₋ₓ (0≦x<1) layer is formed by either ion implantation or a diffusion method. Thereafter, carbon is used to alter the SiₓGe₁₋ₓ (0≦x<1) layer, to form the SiₓGe₁₋ₓC (0≦x<1) altered layer 202. For example, alteration of the SiₓGe₁₋ₓ (0≦x<1) layer by carbon can be conducted by subjecting the silicon crystal surface to thermal process under an atmosphere of a hydrocarbon gas such as methane, ethane, and propane.

Next, the SiₓGe₁₋ₓC (0≦x<1) epitaxial crystal 104 is formed on the SiₓGe₁₋ₓC (0≦x<1) altered layer 202 as shown in FIG. 2C. Thereafter, the Group 3-5 compound semiconductor crystal 106 is formed on the SiₓGe₁₋ₓC (0≦x<1) epitaxial crystal 104 by selective epitaxial growth to form the semiconductor wafer 200.

Since the semiconductor wafer 200 includes a SiₓGe₁₋ₓC (0≦x<1) altered layer 202 between the silicon crystal of the base wafer 102 and the SiₓGe₁₋ₓC (0≦x<1) epitaxial crystal 104. Therefore, the SiₓGe₁₋ₓC (0≦x<1) epitaxial crystal 104 lattice-matches the silicon of the base wafer 102. Because the semiconductor wafer 200 has this configuration, the crystallinity of the SiₓGe₁₋ₓC (0≦x<1) epitaxial crystal 104 is enhanced.

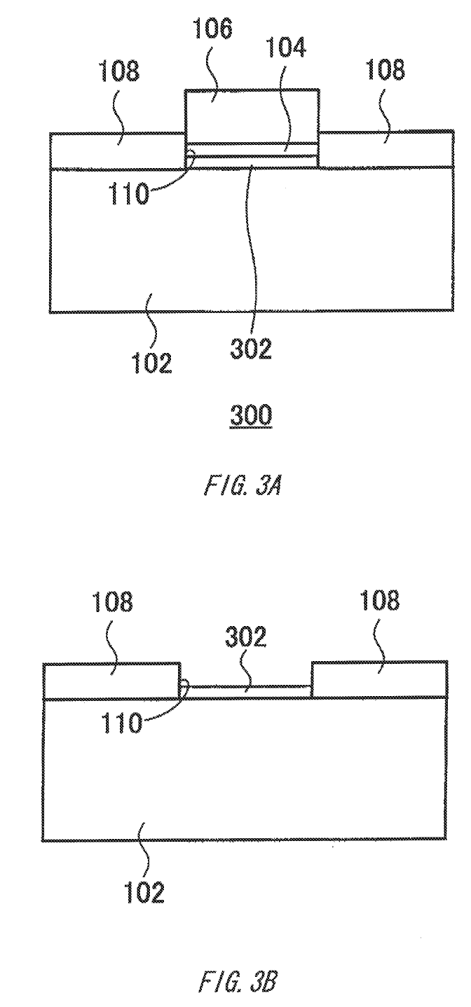

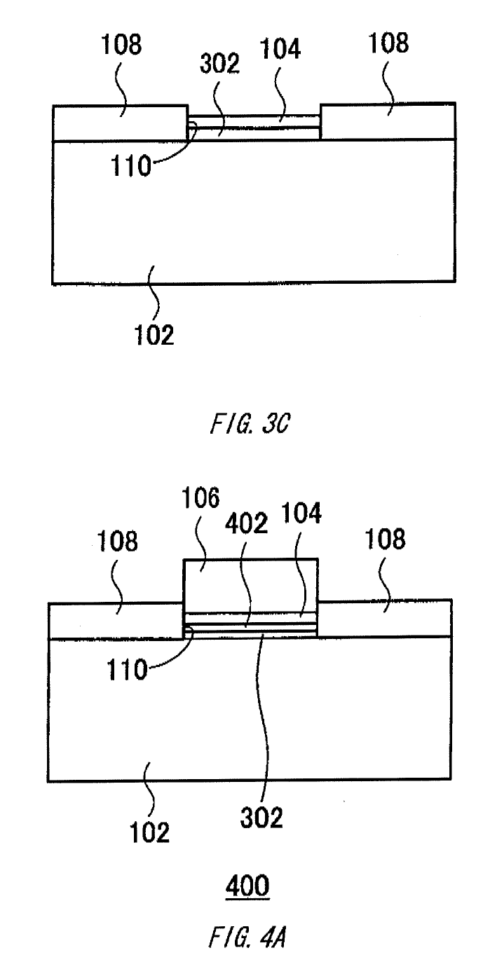

FIG. 3A shows an exemplary cross section of a semiconductor wafer 300. FIG. 3B and FIG. 3C show an exemplary cross section of the semiconductor wafer 300 in its production process. The semiconductor wafer 300 is similar to the semiconductor wafer 100 except that the semiconductor wafer 300 includes a SiₓGe₁₋ₓ (0≦x<1) epitaxial layer 302 between the silicon crystal of the base wafer 102 of the semiconductor wafer 100 and the SiₓGe₁₋ₓC (0≦x<1) epitaxial crystal 104. The following explanation focuses on the difference.

The SiₓGe₁₋ₓ (0≦x<1) epitaxial layer 302 is a layer formed by epitaxial growth between the silicon layer of the base wafer 102 and the SiₓGe₁₋ₓC (0≦x<1) epitaxial crystal 104. The SiₓGe₁₋ₓ (0≦x<1) epitaxial layer 302 may be one or more semiconductor layers selected from among a P-type semiconductor layer and an N-type semiconductor layer constituting a PN-junction isolation. For example, when the silicon crystal is doped to P-type, the PN-junction isolation can be formed if the SiₓGe₁₋ₓ (0≦x<1) epitaxial layer 302 includes an N-type semiconductor layer. So as to cause the SiₓGe₁₋ₓ (0≦x<1) epitaxial layer 302 to have a PN-junction isolation, it is also possible to incorporate a P-type semiconductor layer and an N-type semiconductor layer in the SiₓGe₁₋ₓ (0≦x<1) epitaxial layer 302.

The SiₓGe₁₋ₓ (0≦x<1) epitaxial layer 302 may include a plurality of sets of PN-junction isolation layers made of P-type semiconductor layers and N-type semiconductor layers constituting a PN-junction isolation. For example, the SiₓGe₁₋ₓ (0≦x<1) epitaxial layer 302 may include a P-type semiconductor layer, an N-type semiconductor layer, a P-type semiconductor layer, and an N-type semiconductor layer, in this order.

The SiₓGe₁₋ₓ (0≦x<1) epitaxial layer 302 may also be one or more semiconductor layers selected from among a P⁺type semiconductor layer and an N⁺type semiconductor layer constituting a tunnel junction. For example, when the silicon crystal is doped to P⁺type, the tunnel junction can be formed by incorporating an N⁺type semiconductor layer in the SiₓGe₁₋ₓ (0≦x<1) epitaxial layer 302.

The SiₓGe₁₋ₓ (0≦x<1) epitaxial layer 302 may include a plurality of sets of tunnel junction layers made of P⁺type semiconductor layers and N⁺type semiconductor layers constituting a tunnel junction. For example, the SiₓGe₁₋ₓ (0≦x<1) epitaxial layer 302 may include a P⁺type semiconductor layer, an N⁺type semiconductor layer, a P⁺type semiconductor layer, and an N⁺type semiconductor layer, in this order. The effective impurity concentration of each of the P⁺type semiconductor layer and the N⁺type semiconductor layer is 5×10¹⁸/cm³ or greater and is preferably 1×10¹⁹/cm³ or greater.

The semiconductor wafer 300 may be produced in the following manner. First, as shown in FIG. 3B, an aperture 110 is provided through the inhibitor 108 on the base wafer 102. Next, the SiₓGe₁₋ₓ (0≦x<1) epitaxial layer 302 is formed on the silicon crystal exposed in the aperture 110. Note that the silicon crystal exposed in the aperture 110 may be cleansed by processing it in the hydrogen atmosphere.

Next, as shown in FIG. 3C, the SiₓGe₁₋ₓC (0≦x<1) epitaxial crystal 104 is formed on the SiₓGe₁₋ₓ (0≦x<1) epitaxial layer 302. Thereafter, the Group 3-5 compound semiconductor crystal 106 is formed on the SiₓGe₁₋ₓC (0≦x<1) epitaxial crystal 104 by selective epitaxial growth, to form the semiconductor wafer 300.

Since the silicon crystal of the base wafer 102 contains a certain amount of defects, if there is no SiₓGe₁₋ₓ (0≦x<1) epitaxial layer 302 formed, the SiₓGe₁₋ₓC (0≦x<1) epitaxial crystal 104 will be affected by the defect existing in the base wafer 102. In comparison, the SiₓGe₁₋ₓ (0≦x<1) epitaxial layer 302 is formed by epitaxial growth, and therefore has a lower probability of containing defects. This means that the SiₓGe₁₋ₓC (0≦x<1) epitaxial crystal 104 of the semiconductor wafer 300 will have a high crystallinity, reflecting the favorable crystallinity of the SiₓGe₁₋ₓ (0≦x<1) epitaxial layer 302.

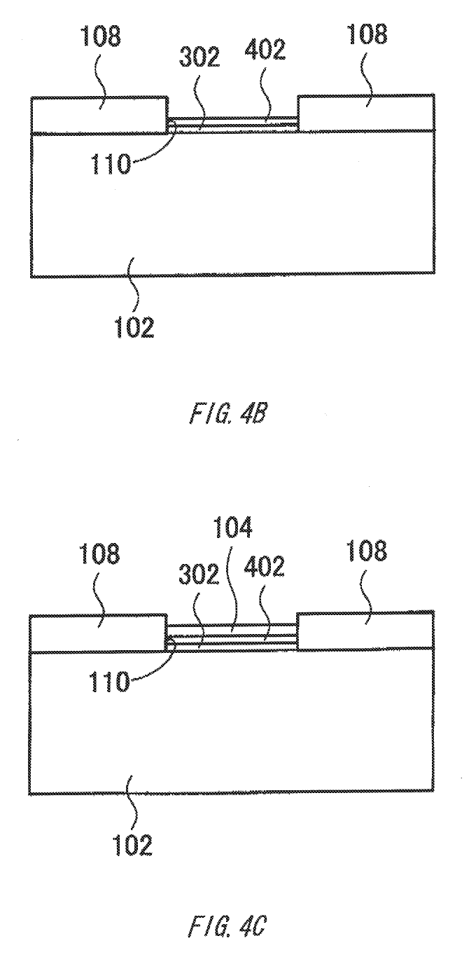

FIG. 4A shows an exemplary cross section of a semiconductor wafer 400. FIG. 4B and FIG. 4C show an exemplary cross section of the semiconductor wafer 400 in its production process. The semiconductor wafer 400 is similar to the semiconductor wafer 300 except that the semiconductor wafer 400 includes a SiₓGe₁₋ₓC (0≦x<1) altered layer 402 between the SiₓGe₁₋ₓ (0≦x<1) epitaxial layer 302 and the SiₓGe₁₋ₓC (0≦x<1) epitaxial crystal 104 of the semiconductor wafer 300. The following explanation focuses on the difference.

The SiₓGe₁₋ₓC (0≦x<1) altered layer 402 is formed between the SiₓGe₁₋ₓ (0≦x<1) epitaxial layer 302 and the SiₓGe₁₋ₓC (0≦x<1) epitaxial crystal 104. The SiₓGe₁₋ₓC (0≦x<1) altered layer 402 is formed by altering the surface of the SiₓGe₁₋ₓ (0≦x<1) epitaxial layer 302 using carbon.

The semiconductor wafer 400 can be produced in the following manner. First, as shown in FIG. 4B, an aperture 110 is provided through the inhibitor 108 on the base wafer 102. Thereafter, the SiₓGe₁₋ₓ (0≦x<1) epitaxial layer 302 is formed on the surface of the silicon crystal exposed in the aperture 110. Furthermore, the SiₓGe₁₋ₓC (0≦x<1) altered layer 402 is formed by altering the surface of the SiₓGe₁₋ₓ (0≦x<1) epitaxial layer 302 using carbon. For example, alteration of the surface of the SiₓGe₁₋ₓ (0≦x<1) epitaxial layer 302 can be conducted by subjecting to the thermal process the surface the SiₓGe₁₋ₓ (0≦x<1) epitaxial layer 302 in an atmosphere of a hydrocarbon gas such as methane, ethane, and propane.

Next, the SiₓGe₁₋ₓC (0≦x<1) epitaxial crystal 104 is formed on the SiₓGe₁₋ₓC (0≦x<1) altered layer 402 as shown in FIG. 4C. Thereafter, the Group 3-5 compound semiconductor crystal 106 is formed on the SiₓGe₁₋ₓC (0≦x<1) epitaxial crystal 104 to form the semiconductor wafer 400.

The semiconductor wafer 400 includes a SiₓGe₁₋ₓC (0≦x<1) altered layer 402 between the SiₓGe₁₋ₓ (0≦x<1) epitaxial layer 302 and the SiₓGe₁₋ₓC (0≦x<1) epitaxial crystal 104. Therefore, the SiₓGe₁₋ₓC (0≦x<1) epitaxial crystal 104 lattice-matches the silicon of the SiₓGe₁₋ₓ (0≦x<1) epitaxial layer 302. Because the semiconductor wafer 400 has this configuration, the crystallinity of the SiₓGe₁₋ₓC (0≦x<1) epitaxial crystal 104 is enhanced.

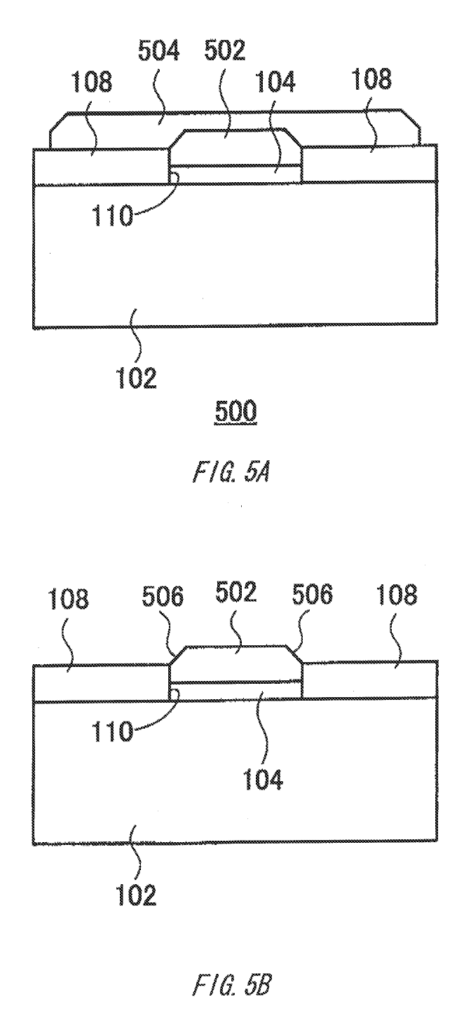

FIG. 5A shows an exemplary cross section of a semiconductor wafer 500. FIG. 5B shows an exemplary cross section of the semiconductor wafer 500 in its production process. The semiconductor wafer 500 contains, as the Group 3-5 compound semiconductor crystal, a first crystal 502 grown in the longitudinal direction and a second crystal 504 grown in the lateral direction along the surface of the inhibitor 108. The surface of the silicon crystal of the base wafer 102 is the (111) plane. The second crystal 504 includes a plane parallel to the surface of the base wafer 102, and the parallel plane is the (111)A plane.

The semiconductor wafer 500 can be produced in the following manner. First, as shown in FIG. 5B, the SiₓGe₁₋ₓC (0≦x<1) epitaxial crystal 104 is formed. Next, the first crystal 502 of the Group 3-5 compound semiconductor whose facet crystal plane 506 in the plane direction different from the (111) plane is exposed is formed (first phase). For example, the first crystal 502 exposed to protrude from the surface of the inhibitor 108 is formed. The first crystal 502 may include facet crystal planes 506 on both sides of the plane parallel to the surface of the base wafer 102.

For example, the facet crystal plane 506 is a low index plane different from the (111) plane. The facet crystal plane 506 is a (1 nm) plane (l, n, and m being an integer), and is preferably a plane satisfying the condition of 1≦|l|+|n|+|m| (absolute value)≦7.

After the first phase, the second crystal 504 of the Group 3-5 compound semiconductor having the (111)A plane parallel to the surface of the base wafer 102 is formed (second phase), with the facet crystal planes 506 serving as seed planes.

In the first phase, the first crystal 502 is formed under the crystal growth condition in which the crystal growth rate in the first direction vertical to the surface of the base wafer 102 is faster than the crystal growth rate in the second direction parallel to the surface of the base wafer 102. The crystal growth rate in all the non-parallel directions to the surface of the base wafer 102 may be set faster than the crystal growth rate in the second direction parallel to the surface of the base wafer 102. By growing the first crystal 502 under such a condition, the first crystal 502 having the facet crystal plane(s) 506 can be formed in a short period of time.

In the second phase, the second crystal 504 is formed under the crystal growth condition under which the crystal growth rate in the second direction is faster than the crystal growth rate in the first direction. The plane of the second crystal 504 grown parallel to the surface of the base wafer 102 of the semiconductor wafer 500 is larger than the plane of the Group 3-5 compound semiconductor crystal 106 shown in FIG. 1A. Therefore, the electronic element can be formed on the semiconductor wafer 500 with a higher level of design freedom.

In all the semiconductor wafer 100 through the semiconductor wafer 500 explained above, the silicon crystal of the base wafer 102 can be cleansed by etching its surface. The Group 3-5 compound semiconductor crystal has its Group 5 atom made of N, and its Group 3 atom made of at least one atom selected from a group consisting of B, Al, Ga, In, Sc, Y, and lanthanoid atoms. The Group 3-5 compound semiconductor crystal may include two or more crystal layers having different compositions from each other. The Group 3-5 compound semiconductor crystal may include two or more crystal layers containing different additive impurities from each other.

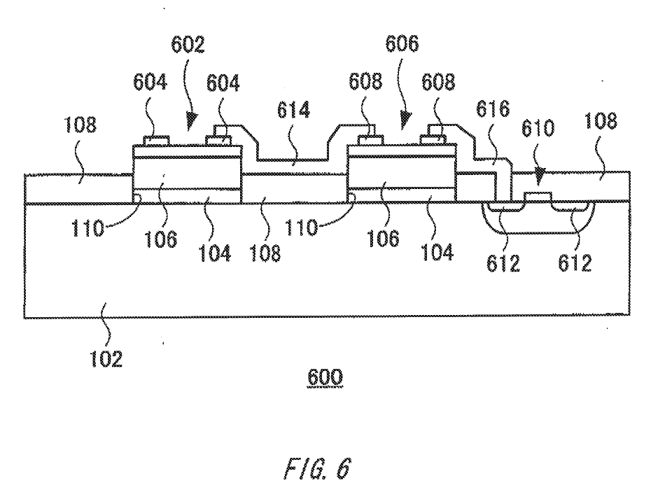

Furthermore, the Group 3-5 compound semiconductor crystal in all the semiconductor wafer 100 through the semiconductor wafer 500 can be used as the active layer of the electronic element. FIG. 6 shows an exemplary cross section of an electronic device 600. The electronic device 600 includes a plurality of Group 3-5 compound semiconductor crystals 106, on each of which either an electronic element 602 or an electronic element 606 is formed.

Of all the plurality of electronic elements, at least two electronic elements (i.e., the electronic element 602 and electronic element 606) include an electrode 604 and an electrode 608 respectively, and are connected with each other via wiring 614. The electronic element 602 and the electronic element 606 may be connected to each other either in series or in parallel. In addition, the electronic device 600 includes a silicon element 610 formed using the silicon crystal of the base wafer 102, and the silicon element 610 includes a terminal 612. The silicon element 610 and the electronic element 606 are connected to each other by wiring 616.

The claims, specification and drawings describe the processes of an apparatus, a system, a program and a method by using the terms such as operations, procedures, steps and stages. When a reference is made to the execution order of the processes, wording such as “before” or “prior to” is not explicitly used. The processes may be performed in any order unless an output of a particular process is used by the following process. In the claims, specification and drawings, a flow of operations may be explained by using the terms such as “first” and “next” for the sake of convenience. This, however, does not necessarily indicate that the operations should be performed in the explained order.

1. A semiconductor wafer comprising:
a base wafer whose surface is made of a silicon crystal:
a SiₓGe₁₋ₓC (0≦x<1) epitaxial crystal formed in a partial area of the silicon crystal; and
a Group 3 nitride semiconductor crystal formed on the SiₓGe₁₋ₓC (0≦x<1) epitaxial crystal.

2. The semiconductor wafer according to claim 1, further comprising
an inhibitor that is formed on the silicon crystal, contains an aperture exposing the silicon crystal, and inhibits crystal growth, wherein
the SiₓGe₁₋ₓC (0≦x<1) epitaxial crystal is formed in the aperture.

3. The semiconductor wafer according to claim 1, further comprising:
a SiₓGe₁₋ₓC (0≦x<1) altered layer between the silicon crystal and the SiₓGe₁₋ₓC (0≦x<1) epitaxial crystal, the SiₓGe₁₋ₓC (0≦x<1) altered layer being a SiₓGe₁₋ₓ (0≦x<1) layer that is formed on a surface of the silicon crystal and whose surface is altered by carbon.

4. The semiconductor wafer according to claim 1, further comprising
a SiₓGe₁₋ₓ (0≦x<1) epitaxial layer formed by epitaxial growth between the silicon crystal and the SiₓGe₁₋ₓC (0≦x<1) epitaxial crystal.

5. The semiconductor wafer according to claim 4, further comprising
a Siₓ Ge₁₋ₓC (0≦x<1) altered layer between the SiₓGe₁₋ₓ(0≦x<1) epitaxial layer and, the SiₓGe₁₋ₓC (0≦x<1) epitaxial crystal, the SiₓGe₁₋ₓC (0≦x<1) altered layer being the SiₓGe₁₋ₓ (0≦x<1) epitaxial layer whose surface is altered by carbon.

6. The semiconductor wafer according to claim 4, wherein
the SiₓGe₁₋ₓ (0≦x<1) epitaxial layer includes one or more semiconductor layers selected from among a P-type semiconductor layer and an N-type semiconductor layer constituting a PN-junction isolation.

7. The semiconductor wafer according to claim 4, wherein
the SiₓGe₁₋ₓ (0≦x<1) epitaxial layer includes one or more semiconductor layers selected from among a P⁺type semiconductor layer and an N⁺type semiconductor layer constituting a tunnel junction.

8. An electronic device comprising an electronic element having, as an active layer, the Group 3 nitride semiconductor crystal in the semiconductor wafer according to claim 1.

9. The electronic device according to claim 8, wherein
the semiconductor wafer includes the Group 3 nitride semiconductor crystal in each of a plurality of areas of the SiₓGe₁₋ₓC (0<x<1) epitaxial crystal,
the electronic element is formed on each of the Group 3 nitride semiconductor crystals, and
at least two of the electronic elements are connected to each other either in series or in parallel.

10. The electronic device according to claim 8, further comprising
a silicon element formed by using the silicon crystal of the semiconductor wafer, wherein
the silicon element and the electronic element are connected to each other.

11. A method for producing a semiconductor wafer, comprising:
forming an inhibitor to inhibit crystal growth, on a silicon crystal of a base wafer whose surface is made of the silicon crystal;
forming an aperture from a surface of the inhibitor to reach the silicon crystal;
forming a SiₓGe₁₋ₓC (0≦x<1) epitaxial crystal on the silicon crystal exposed in the aperture; and
forming a Group 3 nitride semiconductor crystal on the a SiₓGe₁₋ₓC (0≦x<1) epitaxial crystal.

12. The method according to claim 11 for producing a semiconductor wafer, further comprising
forming a SiₓGe₁₋ₓC (0≦x<1) altered layer by altering, using carbon, a surface of a SiₓGe₁₋ₓ (0≦x<1) layer formed on a surface of the silicon crystal exposed in aperture, wherein
in forming the SiₓGe₁₋ₓC (0≦x<1) epitaxial crystal, the SiₓGe₁₋ₓC (0≦x<1) epitaxial crystal is formed on the SiₓGe₁₋ₓC (0≦x<1) altered layer.

13. A method for producing a semiconductor wafer, comprising:
forming an inhibitor to inhibit crystal growth, on a silicon crystal of a base wafer whose surface is made of the silicon crystal;
forming an aperture from a surface of the inhibitor to reach the silicon crystal;
forming a SiₓGe₁₋ₓ (0≦x<1) epitaxial layer on the silicon crystal exposed in the aperture;
forming a SiₓGe₁₋ₓC (0≦x<1) epitaxial crystal on the SiₓGe₁₋ₓ (0≦x<1) epitaxial layer; and
forming a Group 3 nitride semiconductor crystal on the SiₓGe₁₋ₓC (0≦x<1) epitaxial crystal.

14. The method according to claim 13 for producing a semiconductor wafer, further comprising
forming a SiₓGe₁₋ₓC (0≦x<1) altered layer by altering a surface of the SiₓGe₁₋ₓ (0≦x<1) epitaxial layer using carbon, wherein
in forming the SiₓGe₁₋ₓC (0≦x<1) epitaxial crystal, the SiₓGe₁₋ₓC (0≦x<1) epitaxial crystal is formed on the SiₓGe₁₋ₓC (0≦x<1) altered layer.

15. The method according to claim 11 for producing a semiconductor wafer, further comprising:
cleansing, by etching, a surface of the silicon crystal exposed in the aperture.

16. The method according to claim 11 for producing a semiconductor wafer, wherein
the surface of the silicon crystal is the (111) plane,
forming the Group 3 nitride semiconductor crystal includes:
a first phase of forming a first Group 3 nitride semiconductor crystal whose facet crystal plane in a plane direction different from the (111) plane is exposed; and
a second phase of forming a second Group 3 nitride semiconductor crystal having the (111)A plane parallel to the surface of the base wafer, with the facet crystal plane serving as a seed, wherein
in the first phase, the first Group 3 nitride semiconductor crystal is formed under a condition in which a crystal growth rate in a first direction vertical to the surface of the base wafer is faster than a crystal growth rate in a second direction parallel to the surface of the base wafer, and
in the second phase, the second Group 3 nitride semiconductor crystal is formed under a condition in which the crystal growth rate in the second direction is faster than the crystal growth rate in the first direction.
